(19) United States
(12) Patent Application Publication
(10) Pub. No.: US 2011/0037483 A1
(43) Pub. Date: Feb. 17, 2011

(54) MESS-SENSOR

(75) Inventors: Alexander Scheuermann, St. Lucia (AU); Christof Huebner, Edingen-Neckarhausen (DE); Holger Woersching, Uster (CH); Andreas Bieberstein, Karlsruhe (DE); Rolf Nueesch, karlsruhe (DE); Ruth Haas Nueesch, Karlsruhe (DE); Stefan Schlaeger, Horn-Bad Meinberg (DE); Rainer Schuhmann, Karlsruhe (DE); Rolf Becker, Karlsruhe (DE)

Correspondence Address: OBLON, SPIVAK, MCCLELLAND MAIER & NEUSTADT, L.L.P., 1940 DUKE STREET, ALEXANDRIA, VA, 22314, US

(73) Assignees: KARLSRUHER INSTITUT FUER TECHNOLOGIE, Karlsruhe (DE); HOCHSCHULE MANNHEIM, Mannheim (DE)

(21) Appl. No.: 12/599,045

(22) PCT Filed: May 8, 2008
(86) PCT No.: PCT/DE2008/000783

§ 371 Date: Oct. 21, 2010

(30) Foreign Application Priority Data
May 8, 2007 (DE) 10 2007 022 039.3

(51) Int. Cl. G01R 27/06

(52) U.S. Cl. 324/644

(57) ABSTRACT

The invention relates to a sensor having a conductor arrangement and an intervening dielectric to detect local sensor impedances in response to external forces. The conductor arrangement comprises elongate conductor strips between which the intervening dielectric is arranged as a compressible insulating medium.

The present invention refers to the matter claimed in the preamble and thus relates to sensors which respond to forces acting on them.

There is a large number of cases in which sensors are needed by means of which it is possible to detect not only the occurrence of forces but also to determine the point at which a force application occurs. This is desirable especially when deformations of very large structural elements or structures must be expected. As an example, the monitoring of mining constructions can be mentioned in which forces occurring indicate movements of the underground rock which must be located so that countermeasures can be taken, for example additional supports. The same applies to the internal formwork of tunnel structures or to the measurement of pressure in or on concrete in tunnel, underground or above ground construction. Movements of the earth can also lead to pressure changes in pits or boreholes, that is to say to changes in the distribution of forces in the underground, to other structural elements etc. This is frequently critical because, on the one hand, very large areas or distances must be monitored but, on the other hand, a change can occur at any time and it is then necessary to rapidly react to it. Regardless of this problem, the appropriate measurements should be possible at low cost.

It has already been proposed to determine deformations of the underground via time domain reflectometry (TDR hereinafter). With respect to time domain reflectometry, various general introductions will first be pointed out. Especially mentioned should be “Theorie der Zeitbereichsreflektometrie” (Theory of time domain reflectometry) by Dieter Dahlmeyer, in elektronik Industrie 2-2001. In one application, a steep-edge pulse is fed into a coaxial cable. A coaxial cable has a certain impedance, i.e. a certain wave impedance which depends on the geometry of the cable, among other things. As long as the pulse encounters a constant impedance during its propagation along the cable, once it has been fed in, it passes unchanged along the cable apart from any attenuation due to cable losses. However, if the impedance along the signal path, i.e. the cable, changes, a part of the pulse is not forwarded but reflected. This is comparable to the reflection of a light wave at a boundary surface such as a water surface: as long as the light wave can propagate undisturbed, it runs in a fixed predetermined direction. It is only at a boundary surface at which the propagation characteristic (and thus also the impedance for light waves) changes that a part of the light is reflected whilst another part continues.

At the feeding end of the cable an examination is then carried out as to whether a particular part of the pulse originally fed in is reflected and after which time reflected voltage pulse components are observed; this time allows the position of the impedance change to be inferred.

From Kane Geotech Ing., Stockton, Calif., it is known to introduce electrical coaxial cables into boreholes and then to determine the cable signature by means of time domain reflectometry. By this means, landslide movements are to be determined which result in a severe kink in a coaxial cable introduced transversely to the slide movement, and thus a particularly great change in the cable impedance which leads to especially strong back reflections at the cable.

In an essay “Monitoring Slope Movement with Time Domain Reflectometry” by W. F. Kane, presented in Geotechnical Field Instrumentation: Applications for Engineers and Geologists, sponsored by: ASCE Seattle Section Geotechnical Group and University of Washington Department of Civil Engineering, Apr. 1, 2000, it is stated that each cable has a characteristic impedance which is determined by its material composition and the structure. A particular foam-filled cable is recommended. This should be sheathed. The deformation of the cable would lead to changes in the spacing between the inner and outer conductors. These changes, in turn, would result in impedance differences, as a consequence of which reflection of voltage pulses fed in would occur. It is stated that a so-called cable signature “peak” would indicate the extent of the cable damage. It is stated that ground movements would deform the cable and result in impedance changes and energy reflections of pulses fed in which, in turn, could be utilized for locating shearing movements. It is stated that the cable is advantageous but that there were various disadvantages. Thus, it is stated that the coaxial cable would have to be mandatorily damaged by shearing or stress or a combination of the two effects in order to show a cable signature. Also, a correlation between the TDR pulse peak magnitude and the magnitude of the movement could not be unambiguous. In addition, a direction of movement would not become apparent.

It is also known already to perform moisture measurements along great distances by means of time domain reflectometry. Such measurements of soil moisture are of special significance in the case of dike surveillances. It has also been proposed already, compare U.S. Pat. No. 6,956,381 B2, to press flat flexible waveguides, which are attached to a flexible sleeve which is filled up with material, against an irregularly shaped interior of a borehole wall in order to be able to then determine soil moisture by time domain reflectometry in a localized manner. A further example of a soil moisture determination is found in JP 10062368 A.

From DE 693 00 419 T2, corresponding to EP 0 628 161 B1, a device for leakage detection in pipes is known. In this document, a fluid-conducting line equipped for finding leakages is proposed which is surrounded around its periphery with a flexible conductive material permeable to fluid and which exhibits a number of parallel insulated electrical conductors which are generally arranged in the longitudinal direction along the line and are wound around the outside of the said flexible conductive material, the insulated electrical conductors exhibiting bare conductor elements which are exposed in the adjacent areas of the insulated conductive material at the location of the insulated conductor material which is adjacent to the flexible conductive material. After a leakage of gas from a line under pressure such as a gas line, an instantaneous ballooning of the conductive flexible layer should then occur which, after contact with the exposed area of the signal-conducting elements, changes the resistance between the said conductors which form the signal-conducting elements. This should be measured directly by means of impedance changes.

Furthermore, in U.S. Pat. No. 6,838,622 B2, it is proposed to determine the filling level of a container such as a nuclear container by using a TDR sensor.

Furthermore, reference is made, especially with respect to the moisture measurement, to the publication “Monitoring of Dams and Dikes—Water Content Determination using Time Domain Reflectometry (TDR)”, published in the 13th Danube-European Conference on Geotechnical Engineering, Ljubljana, Slovenia, May 2006. Furthermore, reference is made to the essay “A fast TDR-inversion technique for the reconstruction of spatial soil moisture content” by S. Schlaeger, published in Hydrology and Earth System Sciences 9, 481-492, 2005.

It is desirable to be able to achieve at least partial advances in measurements such as the pressure and deformation measurements mentioned initially and/or to be able to specify how inexpensive and/or reliable measurements can be carried out.

The object of the present invention consists in providing something new for the commercial application.

The solution to this object is claimed in independent form. Preferred embodiments are specified in the subclaims.

The present invention thus proposes in a first basic concept a sensor having a conductor arrangement and a separating dielectric in order to detect local sensor impedance changes in response to external forces, in which it is proposed that the conductor arrangement comprises elongated conductor strips between which the separating dielectric is arranged as a compressible insulating medium.

It has been found that a clever sensor design provides for a not only qualitative statement to be made about the presence or non-presence of earth movements but, instead, even quantitative statements about loads occurring during movements of structural elements, which can occur due to damage or material fatigue leading to force redistribution, are made possible. This is made possible by ensuring that no abrupt changes occur during load applications but a continuously changing signal is obtained during load application. This is possible by means of a compressible insulating medium.

It is preferred if the separating dielectric still insulates completely even in the compressed state. However, it should be pointed out that it would be possible firstly to observe a change in impedance during the compression which is attributable to a continuous change in the conductor geometry in order to then effect a contacting of the conductors in a final state, as is known per se from the prior art. In such a case, an end position of the compression movement could be indicated. In the preferred variant, however, it is precisely this which is prevented because, as a rule, a local contacting of conductors produces changes in the impedance which are so great that quantitative measurements at other locations are impaired.

In a preferred variant, the separating dielectric is protected against water and/or moisture absorption, respectively against the absorption of any fluids which can lead to impedance changes which are not attributable to force application; mention is made here, for instance, of measurements in or on chemical containers in which a swelling effect caused by chemicals could occur and could change the thickness of the separating dielectric. The protection against such fluids can be provided in different ways. It is possible to use a separating dielectric which does not have any, or only closed pores so that no fluids can penetrate into the separator and the latter is protected per se. As an alternative and/or additionally, it is possible to sheath the entire arrangement of conductors and separating dielectrics which, offer several advantages. Thus, the conductors are protected better against corrosion and possibly abrasion when a sensor is inserted into an opening or recess; at the same time, environmental changes, for example due to soil moisture, cannot lead to a change in the measurement values if, for instance, a greater leakage to ground were to occur along the cable as a result of moisture.

At the same time, it is possible to provide, in addition to the separating dielectric constructed as compressible insulating medium which is protected against water and/or moisture absorption, a separating dielectric intended for moisture absorption. If necessary, this allows measurements to be carried out in dependence on the soil moisture without having to engage in greater expenditure for the sensor technology. Such force/moisture measurements are of special significance in a multiplicity of structures such as dikes, but also for pit enclosures, etc. It is possible to make a distinction between material-related, moisture-change-coupled signals, on the one hand, and purely static or tectonic signals, on the other hand. It should be mentioned, for example, that, if necessary, a measurement with a conductor directly against the surrounding soil would also be possible.

The separating dielectric layer, constructed as compressible insulating medium, of the present invention is preferably sandwiched between two conductor strips. This results in especially stable sensors which can be easily placed.

In a preferred variant, the separating dielectric will be elastically compressible or exhibit plastic deformation or a significant hysteresis only at higher loads. Using such separating dielectrics is an advantage because, for example, slight vibrations of the underground can be averaged out more easily and, moreover, there is a multiplicity of applications in which the behavior under alternating load must be examined, for example in rail construction for railroads, in bridges and the like.

It is possible to arrange the separating dielectric between a stiffening layer over which the load on the sensor arrangement is distributed over a greater distance. This reduces point-shaped loads, thus reduces a plastic or hysteresis-triggering deformation of the medium and by this means provides for an especially simple measurement since the signals have fewer high-frequency components during a measurement with time domain reflectometry, which has a noise-reducing effect.

In a preferred embodiment, the sensor can have quite considerable lengths. Lengths of far more than a meter can be easily produced and used. The essential limitation of the sensor length is a result, on the one hand, of the ever present dielectric loss of the high-frequency measuring and reflection pulse running along the conductor arrangement and disturbances due to the occurrence of multiple reflections, for example between two sensor positions changed in their impedance due to external forces but spaced apart from one another. Nevertheless, it can be appreciated that a sensor can have a length of some decameters. This enables the performance of especially measurements also in long tunnels, suspension bridges and the like. On longer sensors it was found that the speed of propagation of a pulse fed into the sensor cable arrangement in time domain reflectometry does not change, or hardly significantly, under the action of force, i.e. with separating dielectric compression. This leads to a particularly simple signal evaluation.

In an especially preferred variant, a plastic, particularly a foamed plastic is used as separating dielectric, the plastic foaming producing the compressibility. To prevent the penetration of fluids and/or moisture, a plastic hermetically surrounding the conductors is typically preferred.

Protection is also claimed for using a time domain reflectometry sensor, especially as described in a general or preferred form in the text above, in order to quantify deformations and mechanical pressures. Uses that may be mentioned are, in particular, pit enclosures, determination of deformations of embankments and ground, pressure and deformation measurements on structural elements for the assessment of structural safety, determination of damage and material fatigue for long-term measurements, especially in underground construction, preferably in a moisture-distribution-corrected manner, especially for the separation between environmental conditions such as signals linked to moisture changes, etc., and changes on the basis of, e.g., tectonic rock pressures and the like. This is of advantage, e.g. if it is intended to observe hillsides endangered by landslides in order to be able to deliver a long-term behavior prognosis which is easily possible due to the analyzability of the measurements obtained with the present sensor and the great sensor lengths. In general, however, it is not only natural environments but also building constructions which can be checked. It should be mentioned that, apart from long-term measurements, more short-term measurements are also possible. This applies especially in the monitoring of pits in which relatively great pressure changes can occur in the short term in the environment in the course of the excavating progress, which changes must be monitored in the case of large structures. Impending damage can thus be detected early by means of the invention. With respect to the corresponding prior art, the publication by Paul A. Walter, Empfehlung des Arbeitskreises 3.3—Versuchstechnik Fels der Deutschen Gesellschaft für Geotechnik e.V.: Messung der Spannungsänderung im Fels and an Felsbauwerken mit Druckkissen—Bautechnik [Recommendation of Study Group 3.3—Trial technology for rocks of the German Registered Association for Geotechnology: measuring the change in the state of stress in rocks and on rock structures using the pressure pad construction technique], 81: 639-647, should be pointed out as well. Differently from what has been proposed there, the monitoring here is not point-shaped but line-shaped which provides significant advantages. Moreover, planar measurements can be easily detected by using only a few linear sensors. It should be mentioned that by means of the present invention, geological and geotechnical observations can be predicted, for example borehole blow-outs, since, as a rule, such forecasting is especially desirable.

The use of the sensor arrangement for detecting pressure distributions with regard to orientation and strength and for determining moisture distributions in a continuous or quasi-continuous manner and resolved with respect to time should be mentioned as being especially preferred.

For the rest, it should be mentioned that it is possible to use separating dielectrics which are sufficiently temperature-stable to be used with the aforementioned measuring purposes also in deep boreholes or far below the ground. It is possible to determine deformation and pressure distributions with a great information density, processes coupled with moisture such as swelling, shrinking, cracking and/or stress relief, especially if moisture is measured in parallel and/or in alternation. The measurements can be automated without great instrumental expenditure which is particularly preferred for monitoring purposes, the sensors at the same time being cost-effectively producible, and it is easily possible to create sensor configurations which are especially adapted to a respective task, for example by detecting also moisture with a given pressure, performing an adaptation with regard to the operating temperature, performing an adaptation with regard to the expected loads on the sensor by selecting the separating dielectric, performing a load distribution for avoiding point-shaped loads in certain cases, especially by using sensors which are resistant to temperature or resistant to chemicals, all of which significantly expands the spectrum toward industrial monitoring in plant operation, apart from geotechnical applications.

In the text which follows, the invention will be described only by way of example, with reference to the figure drawing in which:

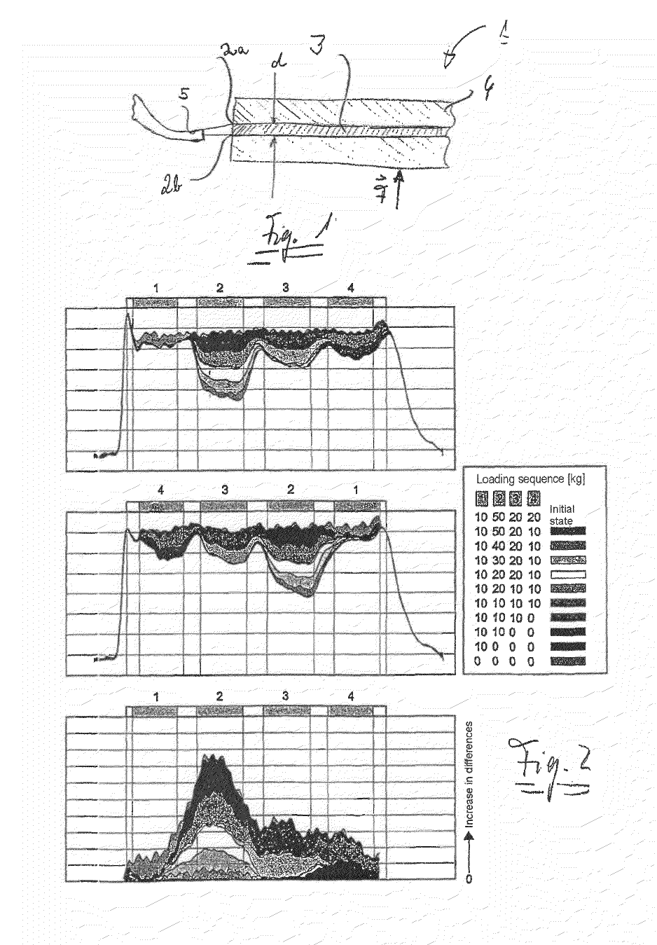

FIG. 1 shows a sensor arrangement of the present invention;

FIG. 2 shows time domain reflection signals which are obtained with different local load applications to a sensor according to FIG. 1, measured once from the left-hand side and once from the right-hand side;

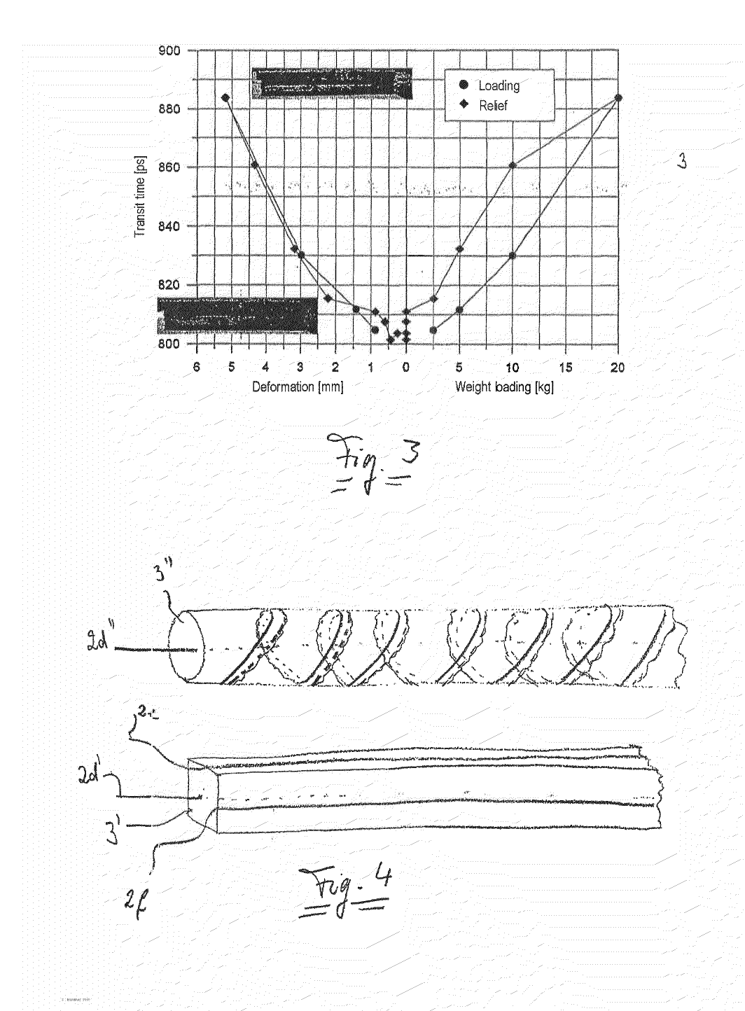

FIG. 3 shows an example of a sensor hysteresis when using a less suitable insulating medium;

FIG. 4 shows alternative sensor geometries.

According to FIG. 1, a sensor 1 generally designated by 1 comprises a conductor arrangement of two conductors 2a, 2b between which a separating dielectric 3 is provided in order to be able to detect local sensor impedance changes in response to external forces, represented by force vector f, the conductor arrangement being formed by elongated conductor strips 2a, 2b between which the separating dielectric is arranged as a compressible insulating medium 3.

In the present case, the sensor 1 is formed as sensor for detecting the local distribution of deformations and mechanical pressures over a relatively long distance of several meters. It is formed to be strip-shaped with a width of, in this case, for example, approx. 2 cm and a thickness of approx. 2.5 cm. In this arrangement, it has an enveloping layer 4 extending outward over the conductor edge above the conductors 2a, 2b, which layer is welded or otherwise sealed at the edges and is formed to be stiffer than the separating dielectric layer 3.

The conductors 2a, 2b are brought out of the sensor at the end and, for the purpose of contacting, are connected to a coaxial cable, compare 5, wherein the joint should not be loaded in use but can be provided with a strain relief and the like. When in use, the coaxial cable will be conducted to a time domain reflectometer.

The conductors 2a, 2b can be copper strips or copper braids formed over the entire width of the sensor arrangement, or can be formed of one or more wires. The construction as copper strips is preferred; the use of other conductor materials such as aluminum, stainless steel and the like should be mentioned. The spacing of the conductors 2a, 2b is constant over the entire length of the sensor in the unloaded state, compare d in FIG. 1.

In the present case, the separating dielectric 3 is formed as closed cellular compressible plastic with an at least largely compression-independent dielectric constant. It is preferred if the separating dielectric does not have any piezoelectric characteristics or the like. The separating dielectric 3 is arranged as continuous layer between conductors 2a, 2b and insulates the latter from one another in any state of the sensor, that is to say both in the no-load state and under compression.

Due to the enveloping layer 4, the separating dielectric is hermetically encapsulated or at least largely protected against the penetration of moisture or other swelling fluids or fluids changing the dielectric constant; the stiffness of the enveloping layer is such that point-shaped loads on the sensor lead to a compression of the separating dielectric which extends over a greater length.

The sensor arrangement of FIG. 1 is used after being installed or inserted into a layer in which forces act in one direction of the surface normal of the separating layer medium 3.

By way of example, the use is explained with measurements from a laboratory trial as follows:

A sensor strip of a given length, in this case of 1 m, is loaded with different weights at four different locations (1, 2, 3, 4 in FIG. 2) along the sensor.

The loading is varied in the course of the trial, compare the table “Loading sequence” which specifies the kilogram loading during the trial.

A time domain reflectometer is used for determining how the sensor responds to the delivery of a steep-edge voltage pulse during the different load applications at different locations. The time domain reflectometer is connected once (upper figure) on the left-hand and once (center figure) on the right-hand sensor side. The difference of the signals from connection on the left-hand and right-hand side is shown in FIG. 2 at the bottom.

From the different curves it can be seen that, with a sensor free of loading, no significant signals which significantly extend beyond the background noise are produced in the time domain reflectometer. In other words, in the unloaded sensor state, the impedance, that is to say the characteristic impedance between conductors 2a, 2b, is constant over the entire sensor length. If then a load is applied to the sensor at one or at several locations, for example with up to 50 kilograms at location 2, distinct pulse reflections are obtained which can be seen in the diagrams. The cause of these pulse reflections lies in the compression of the insulating separating medium which leads to a change in the conductor geometry, in this case to a compression of the conductor 2a against 2b without these contacting one another, however.

The change in the geometry of the conductors 2a, 2b leads to the characteristic impedance changing along the sensor and a steep-edge pulse fed in being partially reflected at the locations of impedance change. For the rest, it should be pointed out that impedance matching elements can be arranged in an appropriate manner in the transition region from the coaxial cable to the sensor arrangement.

FIG. 2 also shows that the forces cannot only be clearly located but also provide quantitative information about forces acting at particular locations. It is worth mentioning that the position of the reflections scarcely changes with the intensity of the loading. This makes it possible to infer a length scale directly from the time scale without having to carry out a complicated analysis.

FIG. 3 shows how a cellular rubber as separating dielectric leads to a hysteresis. The left-hand half of the curve shows the deformation with different load applications and a subsequent load relief. The right-hand half of the figure shows how the transit time of a pulse fed in varies in dependence on a load application or relief. It can be seen clearly that with the separating dielectric used, a hysteresis occurs. It will be appreciated that other separating media apart from cellular rubber, having a lesser hysteresis, are preferred. Using the sensor described, it is easily possible to record deformations over a long term. There is no fear that the measurement values will be influenced by moisture since the sensor and especially the separating medium are protected against moisture. Even so, it can be required in particular cases to also determine the moisture of the underground in addition to the pressure forces. This is mainly appropriate if it is necessary to determine whether forces acting on the sensor are caused by actual ground movements such as a slippage of the underground or changes of the moisture and resultant swelling or shrinking of the environmental material. It is possible to design the sensor differently for such a case.

This will be discussed in the text which follows, further embodiments of a sensor are shown in FIG. 4. These can be used to measure moistures. FIG. 4 shows at the bottom a first sensor having a square separating medium 3′ in the center of which a first conductor 2d extends which in this case is not wide but is constructed as a wire. On two sides of the separating medium 3′, two further conductor wires 2e, 2f are arranged which are lying freely on the outsides. These can be used for measuring the pulse responses when voltage pulses are applied to the conductor pair (2d 2e), (2d 2f) and (2e, 2f).

The pulse response of the sensor to pairs (2d 2e) and (2d 2f), respectively, in each case specifies a deformation in a different direction. The sensor is thus direction-sensitive. If measurements are made between the sensors (2e 2f) and the sensor is placed, for example, in the soil, the impedance, that is to say the characteristic impedance of a pulse propagating along the conductor pair (2e 2f), will also be determined by the characteristics of the surrounding soil and thus be dependent on the underground moisture. By simply measuring different conductor pairs, it is thus possible to determine both the force direction and the ground moisture. This can be advantageous for many applications.

The disadvantageous fact in the sensor shown at the bottom in FIG. 4 is, however, that it must be installed absolutely free of torsion so that the force direction can be determined reliably. The sensor arrangement at the top of FIG. 4 remedies this inasmuch as several conductors are there wound spirally over a separating medium which is constructed to be round in this case. This can be used to perform a measurement with respect to the inner conductor, also shown. Any torsion is more uncritical in this case. By determining the location along which a deformation occurs, it is then possible to infer the direction at the same time. Providing different conductor pairs which can be fitted onto the intermediate conductor 3″, especially also with different slopes, makes it possible to obtain even better information.

In summary, it has been shown that by means of time domain reflectometry, by using a suitable sensor which has been disclosed, measurements with high local resolution are made possible also of such processes which can be considered to be hydraulically/mechanically coupled processes, which enables quantities such as total pressure, suction power to be investigated in moist and swellable materials.

1. A sensor having a conductor arrangement and a separating dielectric in order to detect local sensor impedance changes in response to external forces, characterized in that the conductor arrangement comprises elongated conductor strips between which the separating dielectric is arranged as a compressible insulating medium.

2. The sensor arrangement as claimed in the preceding claim, characterized in that the separating dielectric is arranged for the purpose of insulating at least one conductor pair of the conductor arrangement from one another even in its compressed state.

3. The sensor arrangement as claimed in one of the preceding claims, characterized in that the separating dielectric is protected against water and/or moisture absorption.

4. The sensor arrangement as claimed in one of the preceding claims, characterized in that more than two conductors and/or more than one dielectric are provided.

5. The sensor arrangement as claimed in one of the preceding claims, characterized in that a further dielectric is provided and/or constructed for determining moisture.

6. The sensor arrangement as claimed in one of the preceding claims, characterized in that the separating dielectric is sandwiched between two conductor strips.

7. The sensor arrangement as claimed in one of the preceding claims, characterized in that the separating dielectric is elastically compressible and/or exhibits only a slight hysteresis and/or plastic deformation under typically expected maximum loads.

8. The sensor as claimed in one of the preceding claims, characterized in that a load-distributing stiffening layer is allocated at least on one side, preferably on both sides to the conductor/separating dielectric arrangement and/or effects the conductor load distribution.

9. The sensor arrangement as claimed in one of the preceding claims, characterized in that the conductor tracks have a total length >1 m, especially >5 m, especially preferably >10 m.

10. The sensor arrangement as claimed in the preceding claim, characterized in that a foamed plastic is used as separating dielectric.

11. The sensor as claimed in one of the preceding claims, characterized in that corrosion-resistant conductors, especially of copper and/or stainless steel, are used.

12. The use of a sensor, especially as claimed in one of the preceding claims, for detecting the local distribution of deformations and/or mechanical pressures by means of time domain reflectometry, elongated sensors with mutually movable, especially reversibly movable conductor pairs being deformed in a force- and/or movement-dependent manner and a size of the sensor arrangement dependent on the impedance being determined.
